(19) United States
(12) Patent Application Publication
(10) Pub. No.: US 2020/0411314 A1
(43) Pub. Date: Dec. 31, 2020

(54) Diamond Seed Technology

(71) Applicants: Saladin Quanaah Allah, Niagara Falls, NY (US); Terry Lee Hamilton, Niagara Falls, NY (US)

(72) Inventor: Saladin Quanaah Allah, Niagara Falls, NY (US)

(73) Assignee: HAMILTON & EADES GENETIC RESEARCH and DEVELOPMENT, LLC, Niagara Falls, NY (US)

(21) Appl. No.: 16/880,909

(22) Filed: May 21, 2020

Related U.S. Application Data
(60) Provisional application No. 62/868,036, filed on Jun. 28, 2019.

(51) Int. Cl. H01L 21/02; C23C 16/511; C23C 16/27

(52) U.S. Cl. CPC H01L 21/02527; C23C 16/274; C23C 16/511; H01L 21/0262

(57) ABSTRACT

Diamond Seed Technology is a material comprising man-made diamond to pure diamond used as semiconductors or conductors to solve the problem of design life expectancy and durability, power generation and output, heat resistance, propulsion, emissions reduction and its flexibility for existing and future designs. This material can be used for various materials, to produce or modify apparatus' and devices such as semiconductors, conductors, fuel cells, light bulb filament illumination, GUI [Graphical User Interfaces; monitor, television, smart screens, portable devices and etc.], LED's, solar cells/panels/bulbs and wherever semiconductors are used in various industries, land, sea and aerospace transportation, portable uses, stationary installations such residential/commercial properties, technological fields and industries and that utilize GUI [Graphic User Interface].

The following detailed specifications are of the best currently contemplated modes of carrying out exemplary embodiments of the invention. The specifications are not to be taken in a limiting sense, but is made merely for the purpose of illustrating the general principles of the invention, since the scope of the invention is best defined by the appended claims.

### WHAT IS SPECIFIED IS

Diamond Seed Technology uses a plasma gas mixture technique to produce diamond seed material. A material comprising man-made diamond to pure diamond will be used as semiconductors or conductors to solve the problem of design life expectancy and durability, power generation and output, heat resistance, propulsion, emissions reduction and its flexibility for existing and future designs. Before the gas mixture Plasma technique process is applied, the manufacturer or individual may also use a doping process to define the design characteristics of the component or part, before it is converted into a man-made diamond. The doping techniques described in the patent may or not be necessary depending on the design specification of the part. For example the part may already be a semiconductor and only needs to be converted to diamond material.

The diamond structure material produced varies from Microcrystalline Diamond (MCD), Nanostructure Diamond (NSD), Diamond with Boron and Nitrogen (BND), Diamond with only boron addition (BDD) or Diamond structures over a given range defined by the manufacturing design specs. This is defined by this patent as tweaking. Tweaking adjust the material or part design characteristics or design parameters for optimum performance of part or material. Tweaking can be also used during the doping process of the material or part being created, before the Plasma Gas mixture process.

There are doping methods utilize Silicon (SI), Germanium (Ge) or Si combined with Ge, Boron (B), AlAs, GaAs, GaP, GaSb, InAs, InP, InSb, ZnS and ZnTe, just to name a few. This material comprising man-made diamond to pure diamond used as semiconductors or conductors to solve the problem of design life expectancy and durability, power generation and output, heat resistance, propulsion, emissions reduction and its flexibility for existing and future designs. This material can be used for various materials, to produce or modify apparatus' and devices such as semiconductors, conductors, fuel cells, light bulb filament illumination, GUI [Graphical User Interfaces; monitor, television, smart screens, portable devices and etc.], LED's, solar cells/panels/bulbs and wherever semiconductors are used in various industries, land, sea and aerospace transportation, portable uses, stationary installations such residential/commercial properties, technological fields and industries and that utilize GUI [Graphic User Interface].

Man-made diamond to pure diamond is an excellent conductor of heat because of the strong covalent bonding. The thermal conductivity can be controlled during the growth process as the diamond is being manufactured. For example, man-made diamond or pure diamond is strong, chemically inert, and has high thermal conductivity, low coefficient of thermal expansion, making it ideal for fuel cell stresses that the fuel cell undergoes during application use. Man-made diamond offers advantages over present electrode materials, chemical stability and low background current. Man-made diamonds to pure diamonds are corrosion-resistant material that is perfect for electrochemical synthesis, electrochemical kinetics, photoelectrochemistry, electrochemical impedance spectroscopy, replacing traditional electrodes and other fuel components in 5 present-day SOFC, PEM, and other fuel cell technologies. A block diagram will show different instruments needed in the Diamond Seed doping technique.

There are four main diamond process categories that can be tweaked to form many more categories based upon diamond seed gas mixture composition. The four types are:
Microcrystalline Diamond (MCD)
Nanostructure Diamond (NSD)
Diamond with Boron and Nitrogen (BND)
Diamond with only boron addition (BDD)

Each of these four categories are defined by SCCM—Standard Cubic Centimeters per minute of gas mixtures over a predetermine flow rate. When different gases are used at a pre-determined SCCM rate, they produce different diamond crystalline structures. All method claims use the same basic principles to form or convert desired part or material into a man-made diamond or pure diamond structure. These structures are based upon the above four categories: Microcrystalline Diamond (MCD), Nanostructure Diamond (NSD), Diamond with Boron and Nitrogen (BND), Diamond with only boron addition (BDD) and other predetermine diamond structure created by varying gas ratios.

In order to improve the crystalline structure no matter the type we must scratch the desired part with 0.25 um diamond powders for 45-50 min using a ultrasonic process. Then UUT is cleaned in acetone, alcohol, and deionized water for 10 min ultrasonic conditioning technique, then dried with nitrogen gas. All processes must proceed as follows: The UUT (Unit Under Test) or manufactured part must be placed in the 2.45 GHz Plasma machine or similar system. The SCCM gas rate must be setup based on the system specifications. In this case the Seki Diamond System (SDS 6K) 6 kW Microwave Plasma CVD System setup or other scalable system. The UUT must be treated for 10-20 min, based on the size of the part being converted to a diamond crystalline structure.

During this process data is being analyzed by the Redshift, vs Blueshift directivity found in FIG. 1A, FIG. 1B, FIG. 2 and FIG. 3 described in this patent and gas mixture calculations. The spreadsheet along with software helps user determine the gas mixture for the desired diamond material. This part can then be assembled into a desired apparatus and tested by the manufacturer to see if meets their desired design specifications. This process may need to be tweaked to improve design characteristics.

By looking at the basic curve characteristics of a capacitor and the basic principles of a fuel cell, we then have a basic foundation to tweaking or adjusting the material design parameters during the conversion process. There are doping methods Silicon (SI), Germanium (Ge) or Si combined with Ge, Boron (B), AlAs, GaAs, GaP, GaSb, InAs, InP, InSb, ZnS and ZnTe, just to name a few. For a fuel cell production, compensation tweaking during the Diamond Seed Technology process is orchestrated by looking at several different parameters. This process involves adding or subtracting donors or acceptors. This method would convert P-type material to N-type material by adding more donor than acceptors.

Curve characteristics of charging and discharging capacitors are looked at for a baseline in the tweaking process, along with the Nernst equation for EMF, Faraday constant, Universal Gas constant, Resistivity formula and other doping techniques to produce or modify components such as the electrolytes, anode, cathode, interconnect, transistor, capacitor or other integrated material. 4 point probing measuring method to accurately measure the voltage drop and current for the test parameters throughout the process. The 4 point probing method is utilized to minimize the electrical contact resistance between the probes and the contacts. This will be used with the Vector Network Analyzer for accuracy.

These steps must be tweaked [see FIG. 4] for each of the key parts of the Diamond Seed components because each component has its own doping characteristics. Argon-Ion Laser is used in the process for thermal property measures during the fabrication process of the diamond core components. A Fourier Transform InfraRed (FT-IR) Spectrometer FTIR Analysis measures the infrared region of the electromagnetic radiation spectrum. The sample's absorbance of the infrared light's energy at various wavelengths is measured to determine the material's molecular composition and structure. The doping or conversion process does not alter the design characteristics of the components or apparatus, it only enhances its life expectancy and durability, power generation, output and heat resistance. Once components go through the doping or conversion process they can utilized or assembled if necessary.

A Seki Diamond System (SDS 6K) 6 kW Microwave Plasma CVD System or similar gem, tool, and scalable poly diamond production System is centrally used to produce Diamond Seed material. These systems can be scaled up to a larger version to fit larger components that will be converted to Diamond Seed material. Other apparatus' such as a MSA ALTAIR 5X Gas Leak Detector, Cornerstone 260 Monochromator, MCT Infrared Detector, Photo Multiplier H10330 NIR PMT module, Vector Network Analyzer, DATAQ DI-1120 Close-up, MSO58:5-BW-350 Oscilloscope, Dell Laptop Computer 17 R5 17.3″, Dell Main Desktop Computer, LabVIEW Professional Development Computer Software, Matlab Computer Software and optional Vertical Ion Implanter. For example, the SDS 6K System's stable plasma enables long process durations for thick diamond growth, and its friendly user interface and data-logging features make for easy operation. The 6K provides in-situ monitoring of temperature by IR pyrometer and allows the connection of additional metrology tools including an optical emission spectrometer and interferometer for plasma diagnostics and film thickness monitoring. This system may be used in recipe-driven automatic, semiautomatic or manual mode, and it also offers remote Internet capability. It is field proven for high-volume production operation. The SDS 6K System provides an excellent process stability and repeatability; operable in low- to high-power density plasma for accelerated growth rates; unique temperature control capabilities at high power densities; wide pressure operating range: 10-200 Torr; clamshell lid for easy-access substrate placement and chamber cleaning; recipe-driven automatic, semiautomatic and manual control.

Diamond Seed material can be used to produce or modify a fuel cell and its components: Interconnect, Anode, Electrolyte, Cathode, Air Interconnect, Air Electrode, Fuel Electrode. The Interconnect provides sealability of gas or other fuels used to prevent leaking between electrodes and low reactivity between component parts so that fuel cells work as designed. The Anode creates numerous pathways for electron and ion conduction and is good for high temperature stability. The Electrolyte causes high ionic conductivity and high long-term reliability for strength in surrounding layers. The Cathode is a large reaction field for oxygen absorption and ionization. The Air Interconnect provides a pathway for the air to move freely. The Air Electrode provides a pathway of high-density to give high performance instability at high temperatures. The Fuel Electrode creates a pathway for fuel to enter the fuel cell. The doping or conversion process does not alter the design characteristics or components of the fuel cell. The process only enhances the life expectancy and durability, power generation, output and heat resistance of those components and the fuel cell. Once the desired components go through this process the fuel cell can be assembled. See FIG. 5A, FIG. 5B and FIG. 5C in the Drawings.

Diamond Seed material can be used to produce or modify a light bulb and its components: Glass Bulb, Inert Gas, Tungsten Filament, Contact Wire to Foot, Contact Wire to Base, Support Wires, Glass Mount/Support, Base Contact Wire, Screw Threads, Insulation, Electrical Foot Contact. When electricity passes through the diamond seed material tungsten filament it becomes hot and glows. The inert gas conducts the heat generated by the filament to the glass bulb from where the heat is radiated into the atmosphere. The interconnects to complete current flow base upon light bulb technology are the Contact Wire to Foot, Contact Wire to Base, Support Wires, Glass Mount/Support, Base Contact Wire, Screw Threads, Insulation, Electrical Foot Contact. The doping or conversion process does not alter the design characteristics or components of the light bulb. The process only enhances the life expectancy and durability, power generation, output and heat resistance of those components and the light bulb. Once the desired components go through this process the light bulb can be assembled. See FIG. 6 in the Drawings.

Diamond Seed material can be used to produce or modify components used in GUI: [GRAPHICAL USER INTERFACES] such as monitors, televisions, smart screens, portable devices and etc.]: Standard LCD, Plasma, LC and Smart Device display designs which utilize Polarizing Filters, Glass Plates, Dielectric Material and Electronic Circuitry Interconnects. The doping or conversion process does not alter the design characteristics or components of GUI. The process only enhances the life expectancy and durability, power generation, output and heat resistance of those components and GUI. Once the desired components go through this process GUI can be assembled. See FIG. 7 in the Drawings.

Diamond Seed material can be used to produce or modify components used in solar cells, solar panels, solar bulbs or other apparatus' which use solar energy. PV cells on the panels turn sunlight into DC electricity. Solar panels consists of a layer of silicon cells, a metal frame, a glass casing and various wiring to allow current to flow from the silicon cells. When light interacts with a silicon cell it causes electrons to be set into motion which initiates a flow of electric current. The current flows into an inventor, which converts it to AC electricity that is used in all spheres of human activity, technological devices and industries that utilize electricity. Doped and tweaked Diamond Seed Technology will replace standard silicon material to maximize solar cell/panel peak performance and longevity. The Top Contact Layer is used to complete the current path of electric current. Special Anti-Reflecting Coating absorbs the solar energy (photon) and then raises an electron to a higher energy state. Then the flow of this high-energy electron to an external circuit. N-Type silicon semiconductor and P-Type Silicon Semiconductor are called the (N-P junction) that converts the energy of light directly into electricity (DC) using the photovoltaic effect. Bottom Contact Layer is used to complete the current. The Glass Bulb or load that needs to be powered by solar energy. The doping or conversion process does not alter the design characteristics or components of solar cells, solar panels, solar bulbs and other apparatus' which use solar energy. The process only enhances the life expectancy and durability, power generation, output and heat resistance of those components and the solar cells, solar panels, solar bulbs and other apparatus' which use solar energy. Once the desired components go through this process the solar cells, solar panels, solar bulbs and other apparatus' which use solar energy can be assembled. See FIG. 8 in the Drawings.

Diamond Seed material can be used to produce or modify LED's: An Epoxy Case lens allows the light to escape from the semiconductor inside the enclosed shell. It focuses the light at the best viewing angle and protects the components from outside damage. The Wire Bond is an interconnection between the Anode and Cathode to complete current flow. The Reflective Cavity focuses the light to a single point. An Anvil and Post are two leads of an LED that are used to supply input voltage. Diamond Seed material replaces the standard materials to make an LED using man-made diamond or pure diamond doped at specific parameters to obtain desired effects by the manufacturer. The doped material emanates a light when an electrical current is passed through it. The doping or conversion process does not alter the design characteristics of the light bulb or its components, it only enhances the life expectancy and durability, power generation, output and heat resistance of those components and the LED's. Once the desired components go through this process the light bulb can be assembled. The doping or conversion process does not alter the design characteristics or components of LED's. The process only enhances the life expectancy and durability, power generation, output and heat resistance of those components and LED's. Once the desired components go through this process the LED's can be assembled. See FIG. 9 in the Drawings.

### BRIEF DESCRIPTION OF DRAWINGS

FIG. 1A and FIG. 1B

Redshift and Blueshift describes how light shifts toward shorter or longer wavelengths as objects in space (such as stars or galaxies) move closer or farther away from us. The concept is key to charting the universe's expansion. Visible light is a spectrum of colors, which is clear to anyone who has looked at a rainbow.

FIG. 2.

This model describes the Redshift and Blueshift movement. When an object moves away from us, the light is shifted to the red end of the spectrum, as its wavelengths get longer. If an object moves closer, the light moves to the blue end of the spectrum, as its wavelengths get shorter, the light moves to the blue end of the spectrum. This reasoning is used during the plasma formation in the diamond seed chamber to tweak design parameters of part that is being converted to diamond seed material. This is defined by the magnetic field function generated by the 2.5 GHZ waveguide in the test chamber as the gases collide with the electromagnetic field.

FIG. 3.

This figure describes the Diamond Seed process where pure hydrogen or a combination of mix gases (Argon, Nitrogen, and Hydrogen) is ported into the reactor at a predetermined standard cubic centimeter per minute (SCCM) rate. An electric field generated by microwaves ionizes the hydrogen or a combination of mix gases, which ignites a plasma ball inside the reactor. The plasma is created by high frequency and high power KW microwave which is responsible for the growth on the substrate. Then CH4 methane is introduced into the reactor producing carbon growth on the substrate. This is all accomplished in the reactor of the SEKi Diamond or similar man-made diamond producing apparatus.

FIG. 4

Analysis of a plasma ball formation as the gas molecules interact with electromagnetic filed created by the 2.5 GHz mechanism inside the standard CVD chamber process.

FIG. 5A, FIG. 5B, FIG. 5C

A fuel cell is a device that generates electricity through an electrochemical reaction, not combustion. In a fuel cell, hydrogen and oxygen are combined to generate electricity, heat, and water. Fuel cells are used today in a range of applications, from providing power to homes and businesses, keeping critical facilities like hospitals, grocery stores, and data centers up and running, and moving a variety of vehicles including cars, buses, trucks, forklifts, trains, and more. Fuel cell systems are a clean, efficient, reliable, and quiet source of power. Fuel cells do not need to be periodically recharged like batteries, but instead continue to produce electricity as long as a fuel source is provided. A fuel cell is composed of an anode, cathode, and an electrolyte membrane. A typical fuel cell works by passing hydrogen through the anode of a fuel cell and oxygen through the cathode. At the anode site, a catalyst splits the hydrogen molecules into electrons and protons. The protons pass through the porous electrolyte membrane, while the electrons are forced through a circuit, generating an electric current and excess heat. At the cathode, the protons, electrons, and oxygen combine to produce water molecules. As there are no moving parts, fuel cells operate silently and with extremely high reliability. A fuel-cell is an electrical chemical energy conversion to base it utilizes hydrogen and oxygen to generate electricity, heat, and water the hydrogen atoms enter in to the anode the atoms are stripped of their electrons in the cathode the positively charged protons pass through the membrane to the cathode in the negatively charged electrons are force through a circuit generating electricity. After passing through the circuit electrons they are combined with the protons and oxygen from the air to generate the fuel cells by products water and heat.

FIG. 6

Thin glass forms the exterior of the bulb, called the globe. It contains the filament which gives off light, a stem, which holds the filament, and a metal base that screws into a socket, such as in a lamp or ceiling fixture. The outer glass shell of the light bulb is called the globe. The glass ensures maximum light efficiency and provides strong support for the other parts of the bulb. The light bulb has a shape similar to a plant bulb; the rays of light from the filament are much more effective with this shape. The filament inside the light bulb is shaped as a coil to allow the required length of tungsten within its small environment to produce an abundant amount of light. Tungsten is a natural solid metal and a chemical element which is brittle in its raw state but in its purer form is very strong. It has to be, as the filament heats up to a blistering 2,550 degrees Celsius (4,600 degrees Fahrenheit). Within the inner center of the light bulb there is a centralized stem made from glass, which supports the filament in its place. The connecting wires ensure the steady flow of electricity through the components of the light bulb. Similar to the way the human heart works when blood travels to and from the heart, there is a wire that takes the electricity from the base of the light bulb and another wire that completes the electrical circuit back to the base.

Unseen within the light bulb are inert gases usually formed of argon and/or nitrogen. These low-pressure gases prevent the filament inside the bulb from burning out; it also relieves some of the stress on the glass globe from normal atmospheric pressure, lessening the chance of glass breakage. The base of the light bulb has three main functions. First, it securely supports the light bulb within an electrical source unit, like a lamp or a light fixture. The second job of the base is to transfer the electricity from the main electrical source to the inside of the light bulb itself. The last function is to secure the globe and all of the components inside the bulb, creating a reliable and convenient light source.

FIG. 7

More than just computers, GUIs are used in many handheld mobile devices such as MP3 players, portable media players, gaming devices/systems, smart phones and smaller household, office and industrial controls. The GUI [Graphical User Interface] enables humans to interact with electronic devices in the more natural way to communicate with the device and with others.

FIG. 8

Solar energy is the ultimate source of energy, which is naturally replenished in a short period of time, for this reason it is called “renewable energy” or “sustainable energy” source. To take advantages of solar energy, the variety of technologies is used to covert solar energy to heat and electricity. The use of solar energy involves ‘energy conservation’ because it is the way to use energy source that comes from the nature and uses it more wisely and efficiently. That way includes Solar Cell, which is described as follows:

Solar Cell or Photovoltaic (PV) cell is a device that is made up of semiconductor materials such as silicon, gallium arsenide and cadmium telluride, etc. that converts sunlight directly into electricity. When solar cells absorb sunlight, free electrons and holes are created at positive/negative junctions. If the positive and negative junctions of solar cell are connected to DC electrical equipment, current is delivered to operate the electrical equipment. There are three major cell types that classified by its manufacturing technology and the semiconductor.

Single Crystalline Silicon

PV Module

Polycrystalline Silicon

PV Module

Amorphous Silicon

PV Module

Crystalline Silicon PV Module: Two types of crystalline silicon (c-Si) are used to produce PV module; single crystalline silicon or known as monocrystalline silicon and multi-crystalline silicon, also called polycrystalline silicon. The polycrystalline silicon PV module has lower conversion efficiency than single crystalline silicon PV module but both of them have high conversion efficiencies that average about 10-12%. Amorphous Silicon PV Module: Amorphous silicon (a-Si) PV module or thin-film silicon PV module absorbs light more effectively than crystalline silicon PV module, so it can be made thinner. It suits for any applications that high efficiency is not required and low cost is important. The typical efficiency of amorphous silicon PV module is around 6%. Hybrid Silicon PV Module: A combination of single crystalline silicon surrounded by thin layers of amorphous silicon provides excellent sensitivity to lower light levels or indirect light. The Hybrid silicon PV module has highest level of conversion efficiency about 17%.

FIG. 9

Diamond Core Technology replaces the standard materials to make an LED using man-made diamond doped at specific parameters to obtain desired effects by the manufacturer. The doped material emanates a light when an electrical current is passed through it. The material can be doped in different ways to produce different effect as shown below. There are different types of light emitting diodes present and some of them are mentioned below:

Gallium Arsenide (GaAs)—infra-red

Gallium Arsenide Phosphide (GaAsP)—red to infra-red, orange

Aluminium Gallium Arsenide Phosphide (AlGaAsP)—high-brightness red, orange-red, orange, and yellow

Gallium Phosphide (GaP)—red, yellow and green

Aluminium Gallium Phosphide (AlGaP)—green

Gallium Nitride (GaN)—green, emerald green

Gallium Indium Nitride (GaInN)—near ultraviolet, bluish-green and blue

Silicon Carbide (SiC)—blue as a substrate

Zinc Selenide (ZnSe)—blue

Aluminium Gallium Nitride (AlGaN)—ultraviolet

### REFERENCES

1. Resource of physics equations “Physics Formulary By ir. J. C. A. Wevers”
2. Resource of Mathematical concepts Math Book “Calculus Howard Anton 3rd Edition”
3. Fuel Cell concepts “Schmidt-Rohr, K. (2015). “Why Combustions Are Always Exothermic, Yielding About 418 kJ per Mole of O₂”, J. Chem. Educ. 92: 2094-2099. https://doi.org/10.1021/acs.jchemed.5b00333”
4. Semiconductor doping http://hyperphysics.phy-astr.gsu.edu/hbase/Solids/dope.html

What is claimed is:

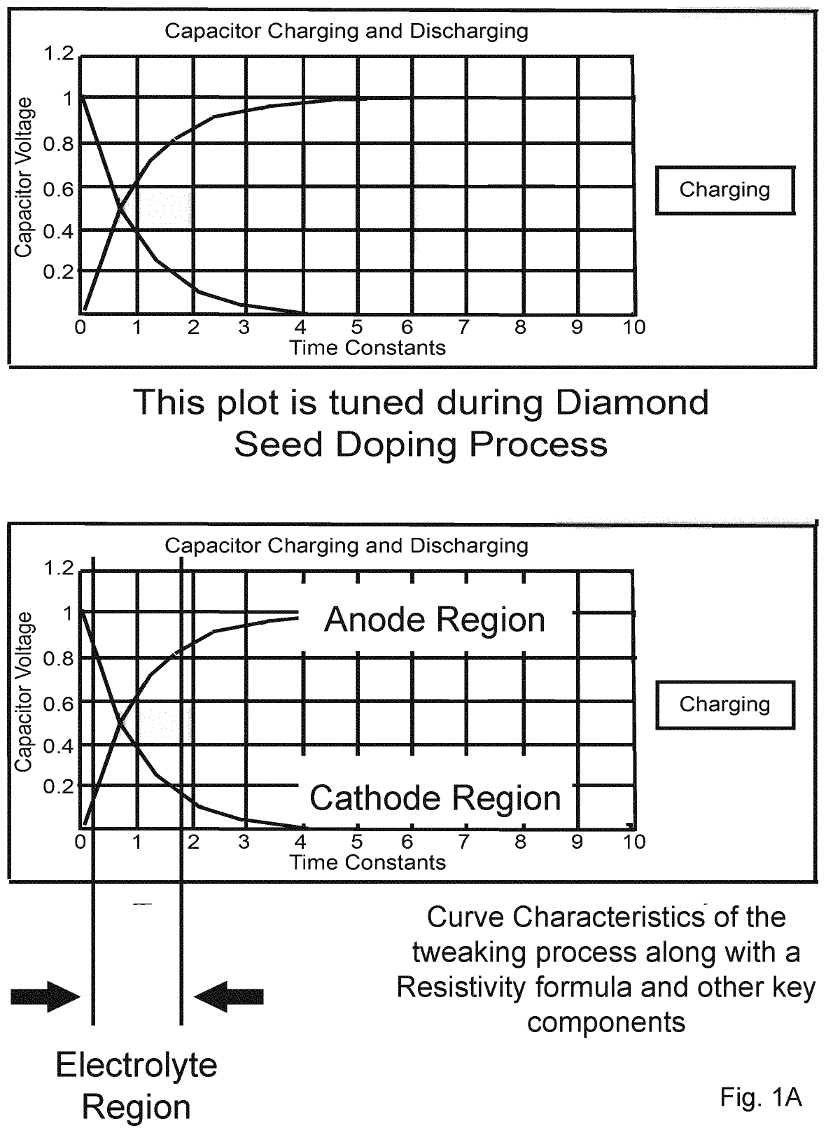

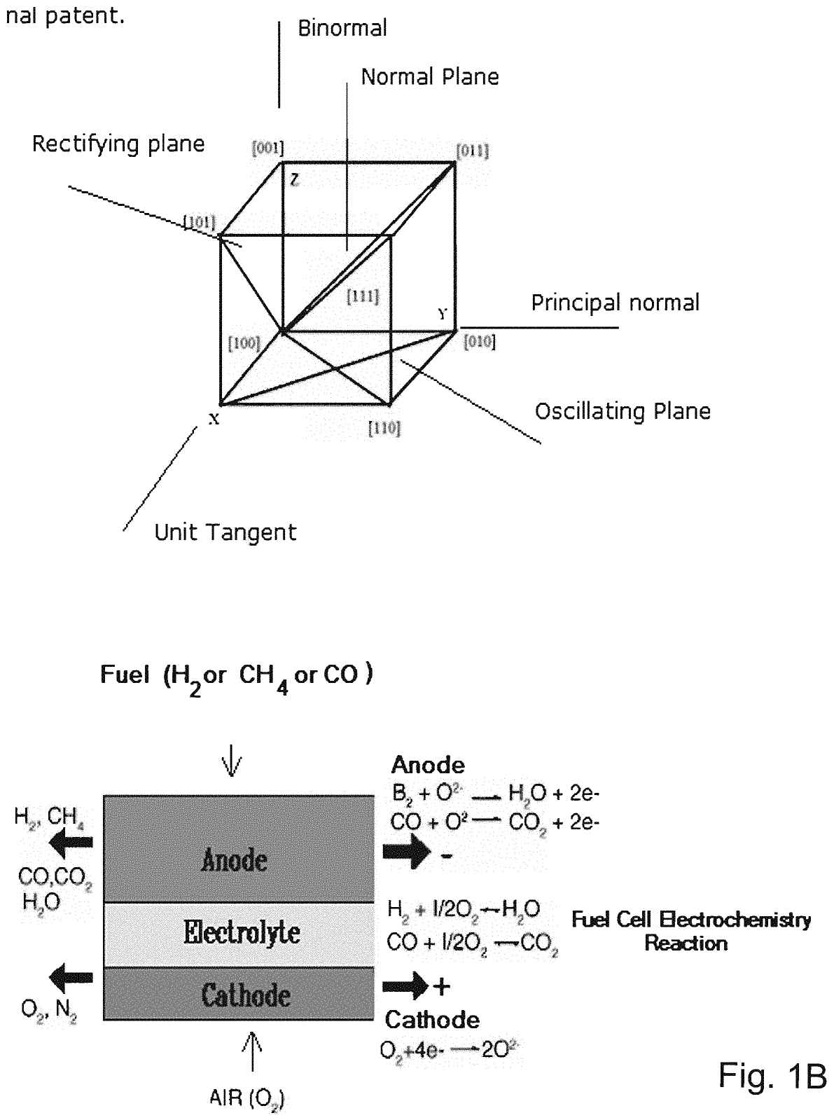

1. A method of using a Plasma gas mixture technique, to produce diamond seed material. A material comprising man-made diamond to pure diamond will be used as semiconductors or conductors to solve the problem of design life expectancy and durability, power generation and output, heat resistance, propulsion, emissions reduction and its flexibility for existing and future designs. Before the gas mixture Plasma technique process is applied, the manufacturer or individual may also use a doping process to define the design characteristics of the component or part, before it is converted into a man-made diamond. The doping techniques described in the patent may or not be necessary depending on the design specification of the part. For example the part may already be a semiconductor and only needs to be converted to a diamond material. The diamond structure material produced varies from Microcrystalline Diamond (MCD), Nanostructure Diamond (NSD), Diamond with Boron and Nitrogen (BND) Diamond with only boron addition (BDD) or Diamond structures over a given range defined by the manufacturing design specs. This is defined by this patent as tweaking. Tweaking adjust the material or part design characteristics or design parameters for optimum performance of part or material. Tweaking can be also used during the doping process of the material or part being created, before the Plasma Gas mixture process.
These doping methods utilize Silicon (SI), Germanium (Ge) or Si combined with Ge, Boron (B), AlAs, GaAs, GaP, GaSb, InAs, InP, InSb, ZnS and ZnTe, just to name a few. This material can be used for various materials, to produce or modify apparatus' and devices such as semiconductors, conductors, fuel cells, light bulb filament illumination, GUI [Graphical User Interfaces; monitor, television, smart screens, portable devices and etc.], LED's, solar cells/panels/bulbs and wherever semiconductors are used in various industries, land, sea and aerospace transportation, portable uses, stationary installations such residential/commercial properties, technological fields and industries and that utilize GUI [Graphic User Interface]. See FIG. 1 in Specifications.

2. A method claim 1, man-made diamond to pure diamond is an excellent conductor of heat because of the strong covalent bonding. The thermal conductivity can be controlled during the growth process as the diamond is being manufactured. For example, man-made diamond or pure diamond is strong, chemically inert, and has high thermal conductivity, low coefficient of thermal expansion, making it ideal for fuel cell stresses that the fuel cell undergoes during application use. Man-made diamond offers advantages over present electrode materials, chemical stability and low background current. Man-made diamonds to pure diamonds are corrosion-resistant material that is perfect for electrochemical synthesis, electrochemical kinetics, photoelectrochemistry, electrochemical impedance spectroscopy, replacing traditional electrodes and other fuel components in 5 present-day SOFC, PEM, and other fuel cell technologies. A block diagram will show different instruments needed in the Diamond Seed doping technique. See FIG. 1A in Specifications.

3. A method claim 1, there are four main diamond process categories that can be tweaked to form many more categories based upon diamond seed gas mixture composition as already mentioned. The four types are:
Microcrystalline Diamond (MCD)
Nanostructure Diamond (NSD)
Diamond with Boron and Nitrogen (BND)
Diamond with only boron addition (BDD)
Each of these four categories are defined by SCCM—Standard Cubic Centimeters per minute of gas mixtures over a predetermine flow rate. When different gases are used at a pre-determined SCCM rate, they produce different diamond crystalline structures. All method claims use the same basic principles to form or convert desired part or material into a man-made diamond or pure diamond structure. These structures are based upon the above four categories: Microcrystalline Diamond (MCD), Nanostructure Diamond (NSD), Diamond with Boron and Nitrogen (BND), Diamond with only boron addition (BDD) and other predetermine diamond structure created by varying gas ratios.

4. A method claim 1, in order to improve the crystalline structure no matter the type we must scratch the desired part with 0.25 um diamond powders for 45-50 min using a ultrasonic process. Then UUT is cleaned in acetone, alcohol, and deionized water for 10 min ultrasonic conditioning technique, then dried with nitrogen gas. All processes must proceed as follows: The UUT (Unit Under Test) or manufactured part must be placed in the 2.45 GHz Plasma machine or system. The SCCM gas rate must be setup based on the system specifications. In this case the Seki Diamond System (SDS 6K) 6 kW Microwave Plasma CVD System setup. The UUT must be treated for 10-20 min, based on the size of the part being converted to a diamond crystalline structure.
During this process data is being analyzed by the redshift, blueshift directivity found in the FIG. 1A system block diagram described in this patent and the gas mixture calculations table. The spreadsheet along with software helps user determine the gas mixture for the desired diamond material. This part can then be assembled into a desired apparatus and tested by the manufacturer to see if meets their desired design specifications. This process may need to be tweaked to improve design characteristics.

5. A method claim 1, by looking at the basic curve characteristics of a capacitor and the basic principles of a fuel cell, we then have a basic foundation to tweaking or adjusting the material design parameters during the conversion process. There are doping methods Silicon (SI), Germanium (Ge) or Si combined with Ge, Boron (B), AlAs, GaAs, GaP, GaSb, InAs, InP, InSb, ZnS and ZnTe, just to name a few. For a fuel cell production, compensation tweaking during the Diamond Seed Technology process is orchestrated by looking at several different parameters. This process involves adding or subtracting donors or acceptors. This method would convert P-type material to N-type material by adding more donor than acceptors.

6. A method claim 1, curve characteristics of charging and discharging capacitors are looked at for a baseline in the tweaking process, along with the Nernst equation for EMF, Faraday constant, Universal Gas constant, Resistivity formula and other doping techniques to produce or modify components such as the electrolytes, anode, cathode, interconnect, transistor, capacitor or other integrated material. 4 point probing measuring method to accurately measure the voltage drop and current for the test parameters throughout the process. The 4 point probing method is utilized to minimize the electrical contact resistance between the probes and the contacts. This will be used with the Vector Network Analyzer for accuracy.
These steps must be tweaked for each of the key parts of the Diamond Seed components because each component has its own doping characteristics. Argon-Ion Laser is used in the process for thermal property measures during the fabrication process of the diamond core components. A Fourier Transform InfraRed (FT-IR) Spectrometer FTIR Analysis measures the infrared region of the electromagnetic radiation spectrum. The sample's absorbance of the infrared light's energy at various wavelengths is measured to determine the material's molecular composition and structure. The doping or conversion process does not alter the design characteristics of the components or apparatus, it only enhances its life expectancy and durability, power generation, output and heat resistance. Once components go through the doping or conversion process they can utilized or assembled if necessary.

7. A method claim 1, wherein a Seki Diamond System (SDS 6K) 6 kW Microwave Plasma CVD System or similar gem, tool, and poly diamond production System is used to produce Diamond Seed material. For example, the SDS 6K System's stable plasma enables long process durations for thick diamond growth, and its friendly user interface and data-logging features make for easy operation. The 6K provides in-situ monitoring of temperature by IR pyrometer and allows the connection of additional metrology tools including an optical emission spectrometer and interferometer for plasma diagnostics and film thickness monitoring. This system may be used in recipe-driven automatic, semiautomatic or manual mode, and it also offers remote Internet capability. It is field proven for high-volume production operation. The SDS 6K System provides an excellent process stability and repeatability; operable in low- to high-power density plasma for accelerated growth rates; unique temperature control capabilities at high power densities; wide pressure operating range: 10-200 Torr; clamshell lid for easy-access substrate placement and chamber cleaning; recipe-driven automatic, semiautomatic and manual control. See FIGS. 1A and 1B in Specifications.

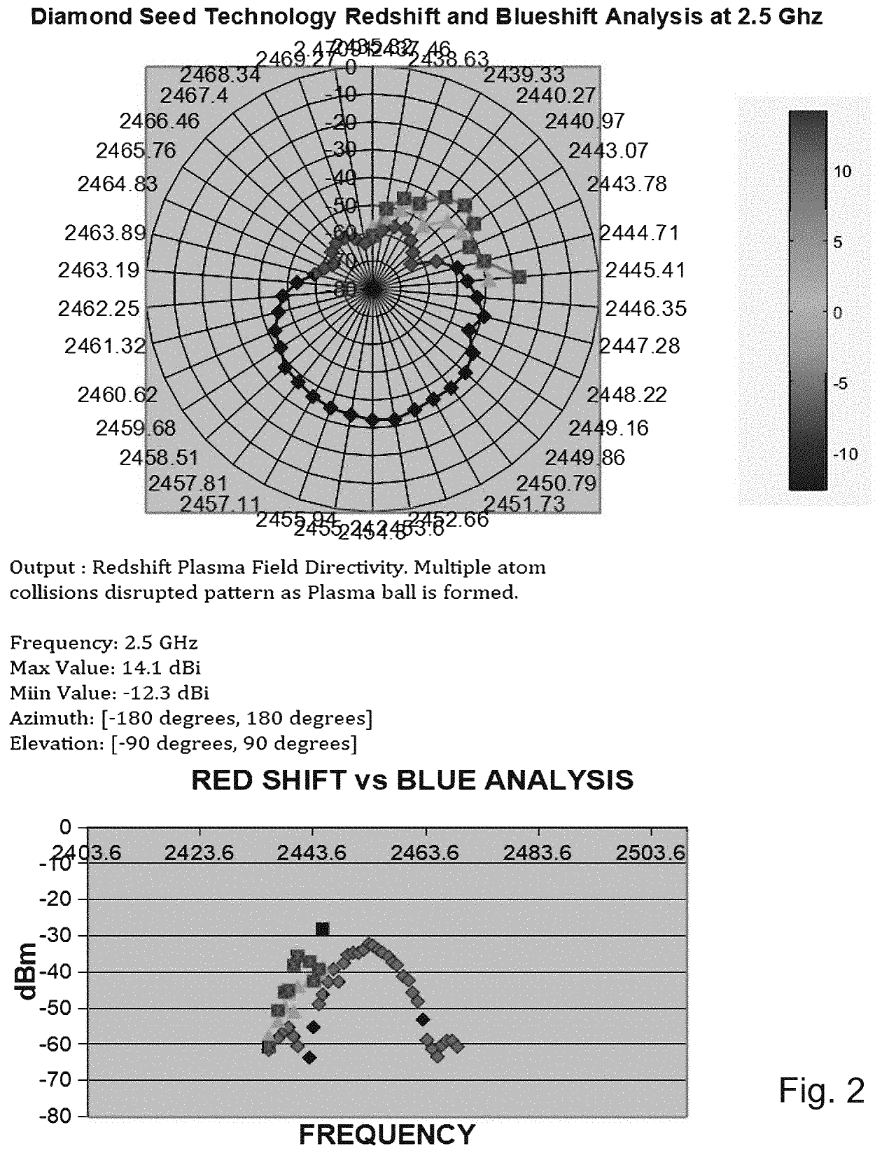

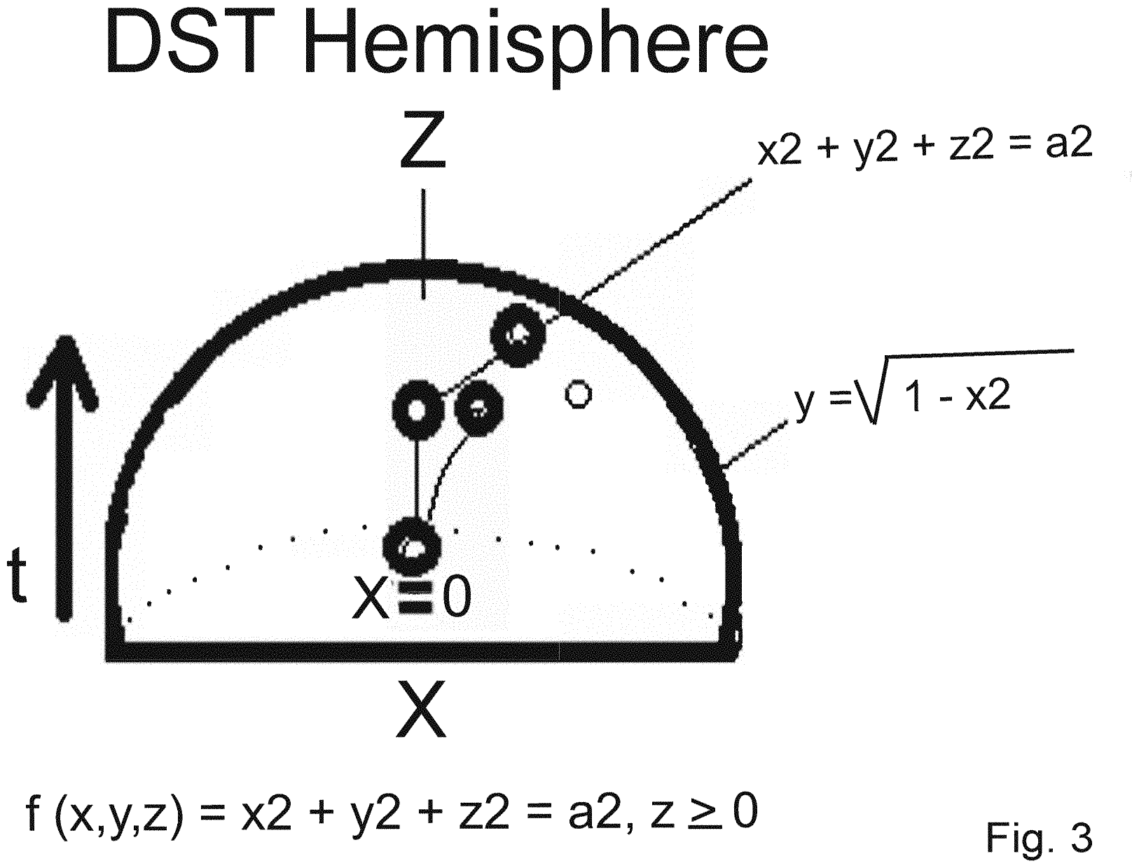

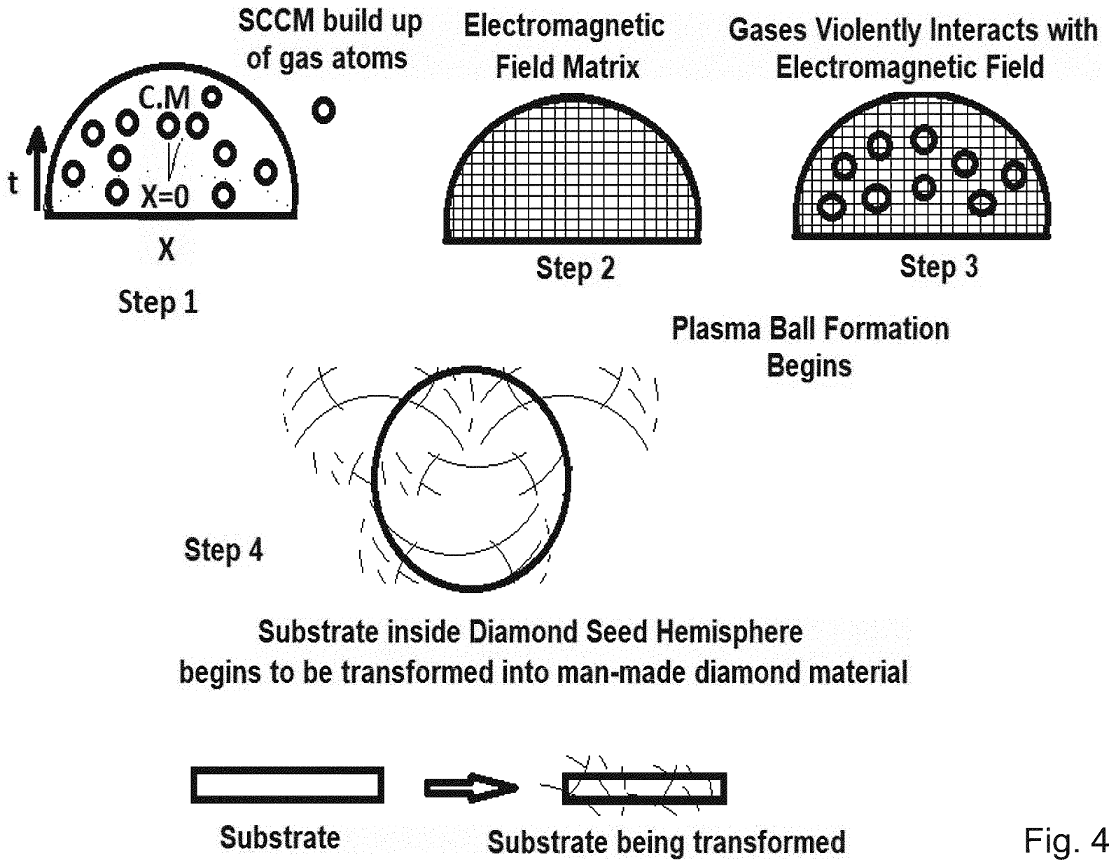

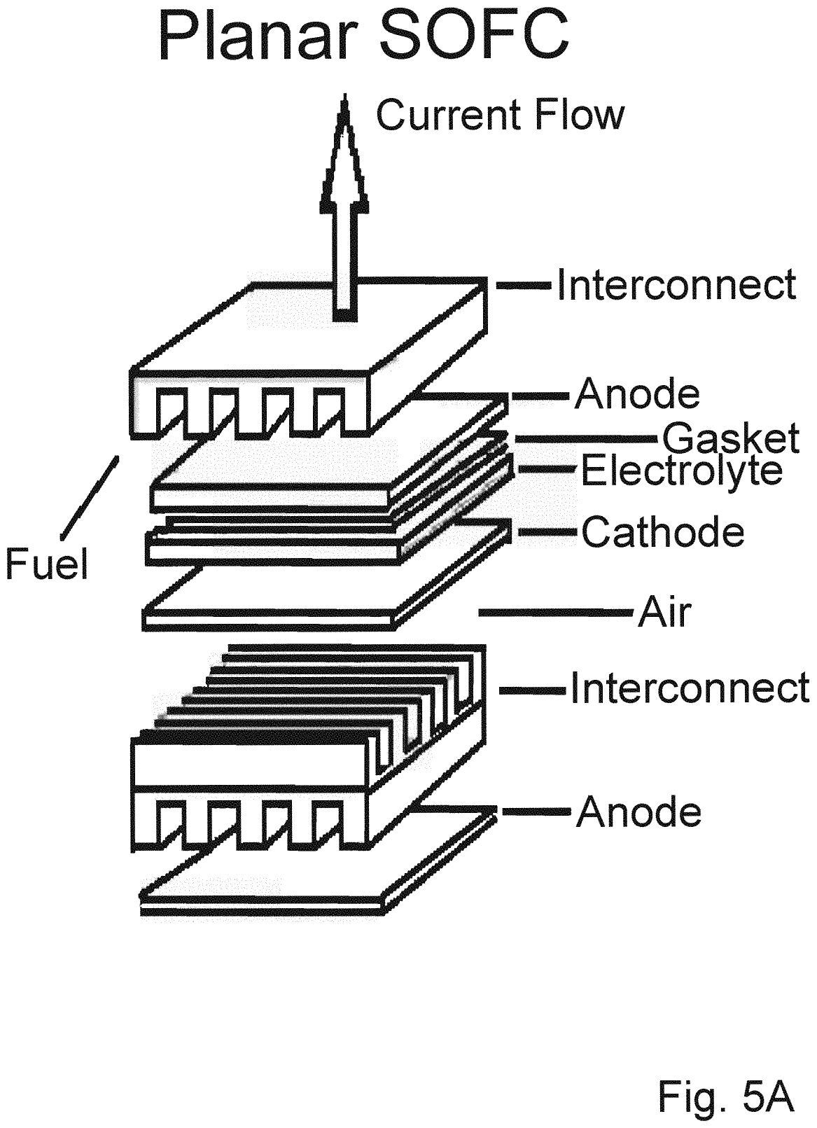

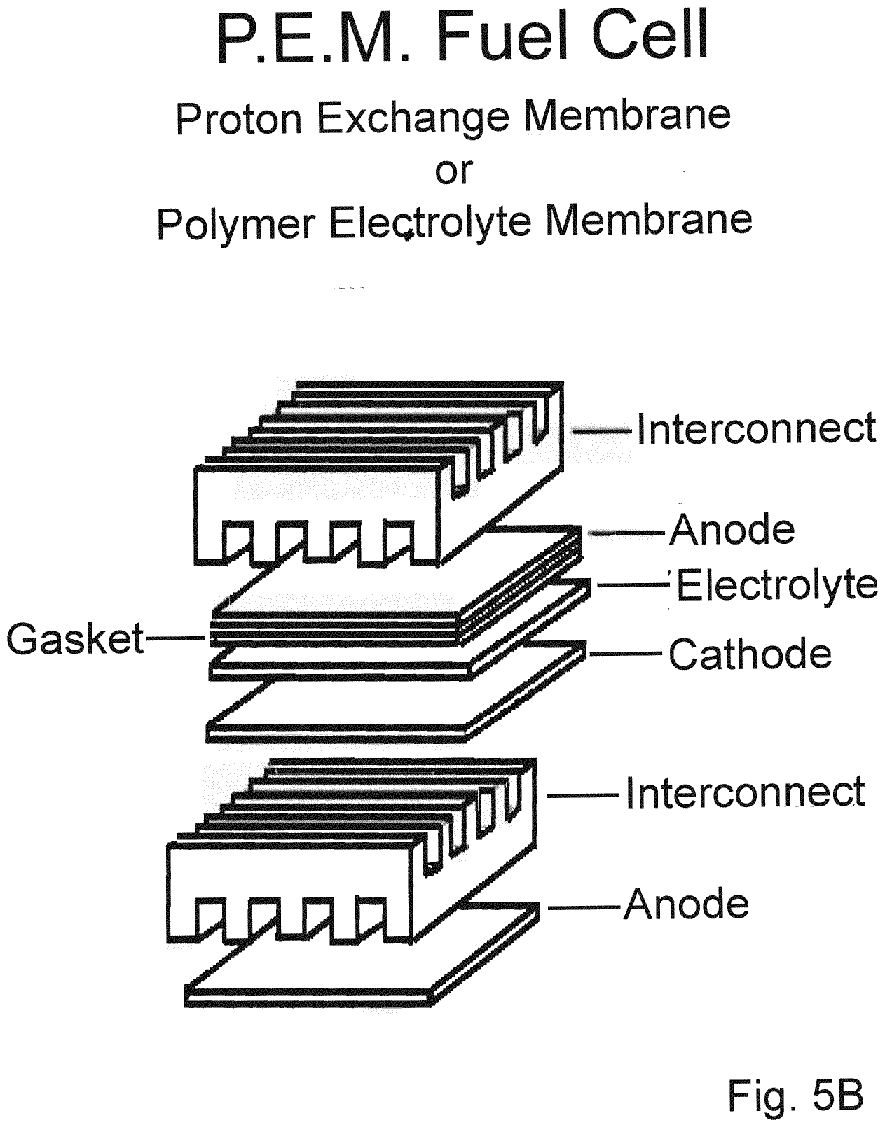

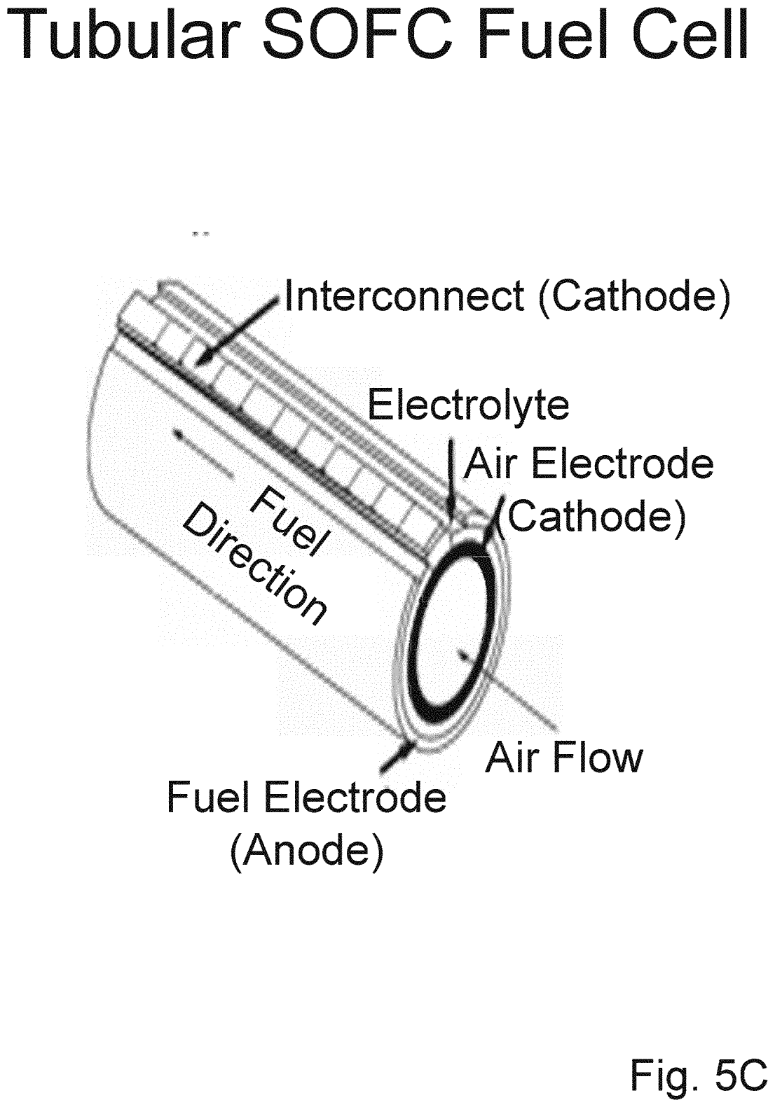

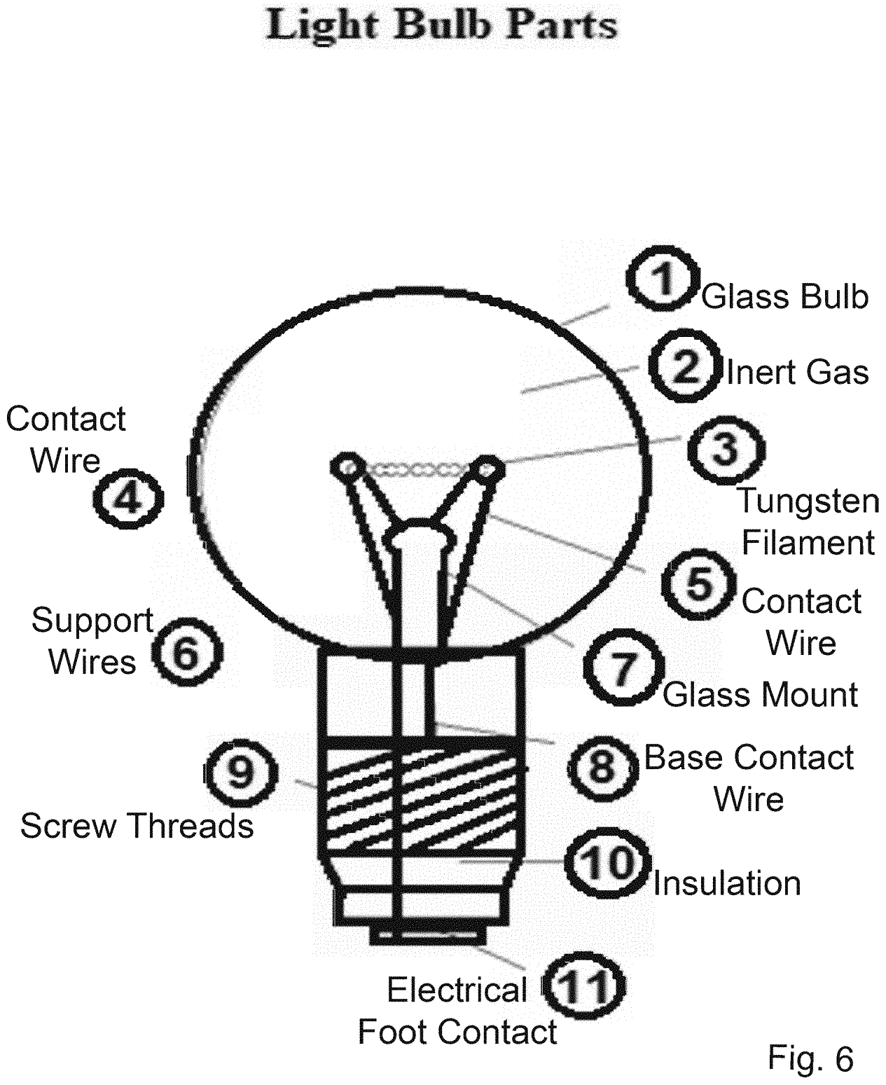

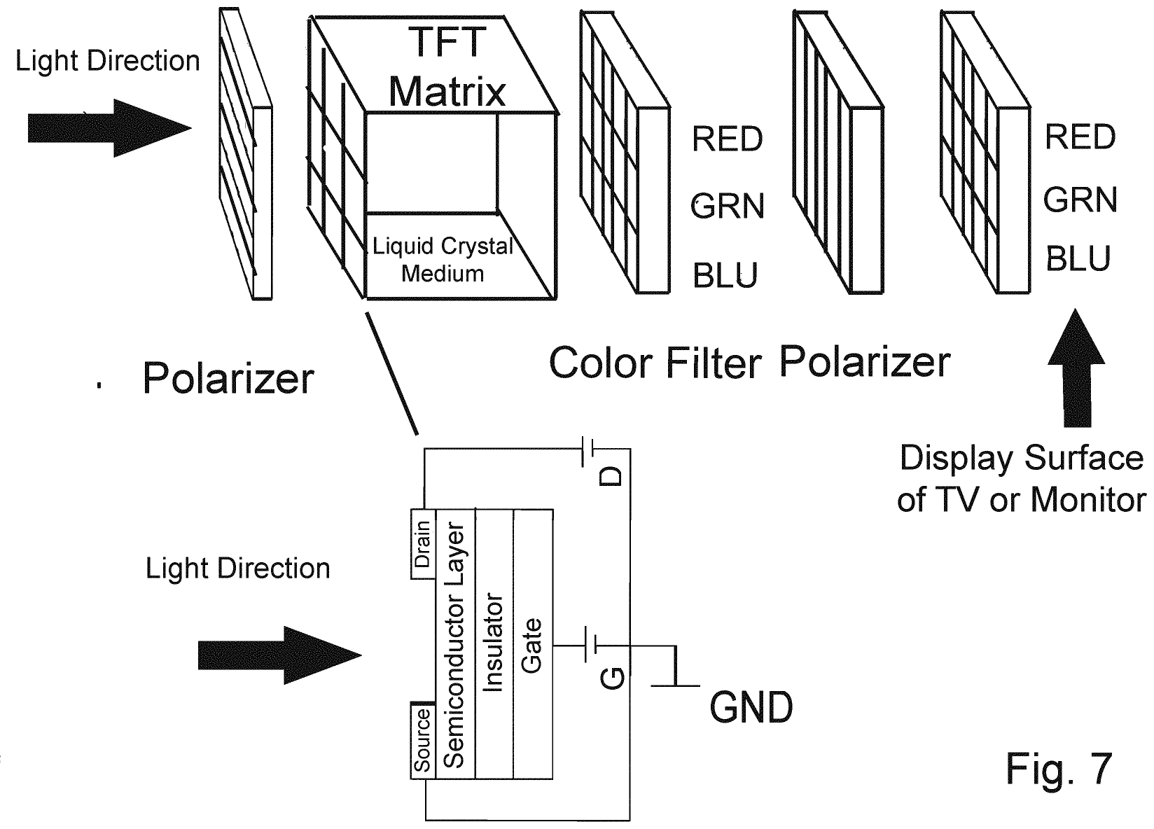

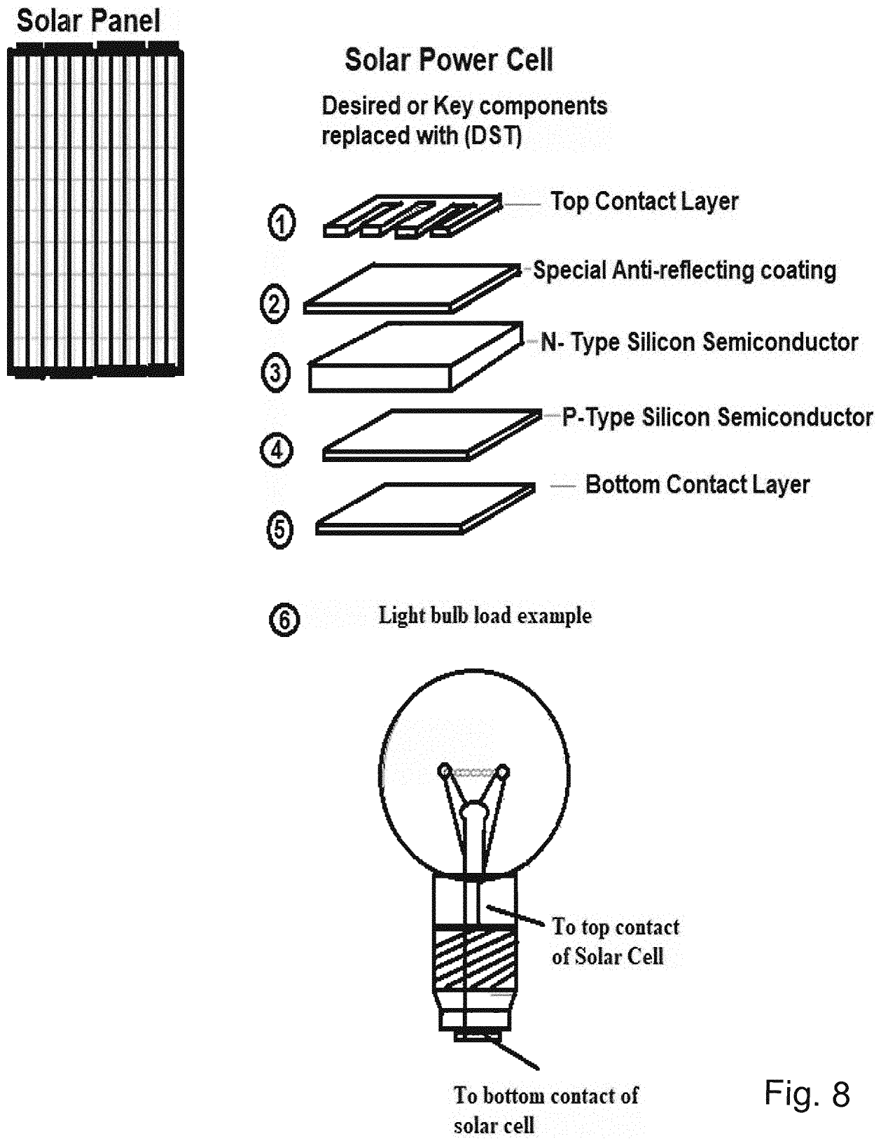

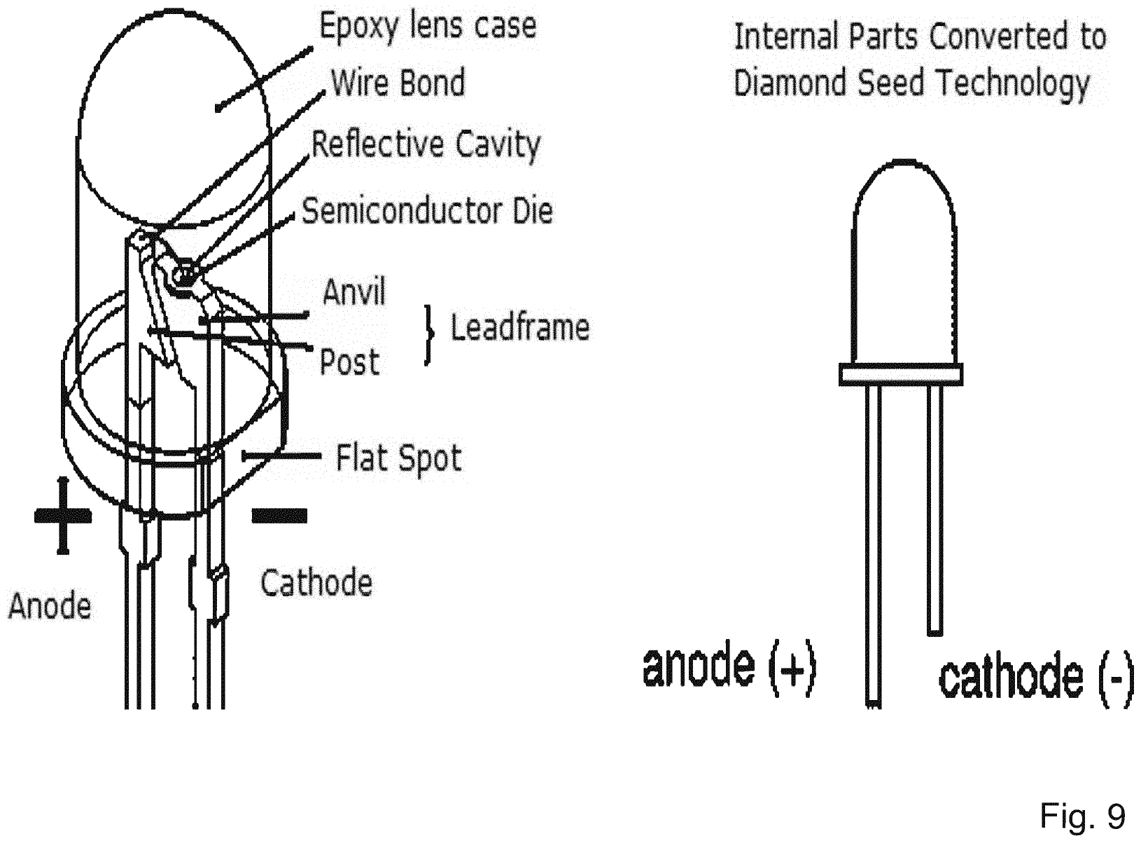

8. A method claim 2, Diamond Seed material can be used to produce or modify a fuel cell and its components: Interconnect, Anode, Electrolyte, Cathode, Air Interconnect, Air Electrode, Fuel Electrode. The Interconnect provides sealability of gas or other fuels used to prevent leaking between electrodes and low reactivity between component parts so that fuel cells work as designed. The Anode creates numerous pathways for electron and ion conduction and is good for high temperature stability. The Electrolyte causes high ionic conductivity and high long-term reliability for strength in surrounding layers. The Cathode is a large reaction field for oxygen absorption and ionization. The Air Interconnect provides a pathway for the air to move freely. The Air Electrode provides a pathway of high-density to give high performance instability at high temperatures. The Fuel Electrode creates a pathway for fuel to enter the fuel cell. The doping or conversion process does not alter the design characteristics or components of the fuel cell. The process only enhances the life expectancy and durability, power generation, output and heat resistance of those components and the fuel cell. Once the desired components go through this process the fuel cell can be assembled. See FIG. 2 in Specifications.

9. A method claim 3, Diamond Seed material can be used to produce or modify a light bulb and its components: Glass Bulb, Inert Gas, Tungsten Filament, Contact Wire to Foot, Contact Wire to Base, Support Wires, Glass Mount/Support, Base Contact Wire, Screw Threads, Insulation, Electrical Foot Contact. When electricity passes through the diamond seed material tungsten filament it becomes hot and glows. The inert gas conducts the heat generated by the filament to the glass bulb from where the heat is radiated into the atmosphere. The interconnects to complete current flow base upon light bulb technology are the Contact Wire to Foot, Contact Wire to Base, Support Wires, Glass Mount/Support, Base Contact Wire, Screw Threads, Insulation, Electrical Foot Contact. The doping or conversion process does not alter the design characteristics or components of the light bulb. The process only enhances the life expectancy and durability, power generation, output and heat resistance of those components and the light bulb. Once the desired components go through this process the light bulb can be assembled. See FIG. 3 in Specifications.

10. A method claim 4, Diamond Seed material can be used to produce or modify components used in GUI: [GRAPHICAL USER INTERFACES] such as monitors, televisions, smart screens, portable devices and etc.]: Standard LCD, Plasma, LC and Smart Device display designs which utilize Polarizing Filters, Glass Plates, Dielectirc Material and Electronic Circuitry Interconnects. The doping or conversion process does not alter the design characteristics or components of GUI. The process only enhances the life expectancy and durability, power generation, output and heat resistance of those components and GUI. Once the desired components go through this process GUI can be assembled. See FIG. 4 in Specifications.

11. A method claim 5, Diamond Seed material can be used to produce or modify components used in solar cells, solar panels, solar bulbs or other apparatus' which use solar energy. PV cells on the panels turn sunlight into DC electricity. Solar panels consists of a layer of silicon cells, a metal frame, a glass casing and various wiring to allow current to flow from the silicon cells. When light interacts with a silicon cell it causes electrons to be set into motion which initiates a flow of electric current. The current flows into an inventor, which converts it to AC electricity that is used in all spheres of human activity, technological devices and industries that utilize electricity. Doped and tweaked Diamond Seed Technology techniques, will replace standard silicon material to maximize solar cell/panel peak performance and longevity. The Top Contact Layer is used to complete the current path of electric current. Special Anti-Reflecting Coating absorbs the solar energy (photon) and then raises an electron to a higher energy state. Then the flow of this high-energy electron to an external circuit. N-Type silicon semiconductor and P-Type Silicon Semiconductor are called the (N-P junction) that converts the energy of light directly into electricity (DC) using the photovoltaic effect. Bottom Contact Layer is used to complete the current. The Glass Bulb or load that needs to be powered by solar energy. The doping or conversion process does not alter the design characteristics or components of solar cells, solar panels, solar bulbs and other apparatus' which use solar energy. The process only enhances the life expectancy and durability, power generation, output and heat resistance of those components and the solar cells, solar panels, solar bulbs and other apparatus' which use solar energy. Once the desired components go through this process the solar cells, solar panels, solar bulbs and other apparatus' which use solar energy can be assembled. See FIG. 5 in Specifications.

12. A method claim 6, Diamond Seed material can be used to produce or modify LED's: An Epoxy Case lens allows the light to escape from the semiconductor inside the enclosed shell. It focuses the light at the best viewing angle and protects the components from outside damage. The Wire Bond is an interconnection between the Anode and Cathode to complete current flow. The Reflective Cavity focuses the light to a single point. An Anvil and Post are two leads of an LED that are used to supply input voltage. Diamond Seed material replaces the standard materials to make an LED using man-made diamond or pure diamond doped at specific parameters to obtain desired effects by the manufacturer. The doped material emanates a light when an electrical current is passed through it. The doping or conversion process does not alter the design characteristics of the light bulb or its components, it only enhances the life expectancy and durability, power generation, output and heat resistance of those components and the LED's. Once the desired components go through this process the light bulb can be assembled. The doping or conversion process does not alter the design characteristics or components of LED's. The process only enhances the life expectancy and durability, power generation, output and heat resistance of those components and LED's. Once the desired components go through this process the LED's can be assembled. See FIG. 6 in Specifications.
